(19) United States
(12) Patent Application Publication
(10) Pub. No.: US 2005/0115670 A1
(43) Pub. Date: Jun. 2, 2005

(54) Method and device for etching a thin conductive layer which is disposed on an insulating plate such as to form an electrode network thereon

(76) Inventors: Armand Bettinelli, Coublevie (FR); Jean-Claude Martinez, Chartres de Bretagne (FR); Jean-Pierre Creusot, Eybens (FR)

Correspondence Address: THOMSON LICENSING INC., PATENT OPERATIONS, PO BOX 5312, PRINCETON, NJ, 08543-5312, US

(21) Appl. No.: 10/493,895

(22) PCT Filed: Oct. 21, 2002
(86) PCT No.: PCT/FR02/03586

(30) Foreign Application Priority Data
Oct. 29, 2001 (FR) 01/13953

(51) Int. Cl. H01L 21/306

(52) U.S. Cl. 156/345.11; 205/666

(57) ABSTRACT

The invention relates to a method and device for etching a thin conductive layer which is disposed on an insulating plate such as to form an electrode network thereon. Before the etching takes place, a protective film, comprising patterns corresponding to the electrodes in the network, is applied, said film being removed after etching. The inventive etching method consists in: moving the plate in the general direction of the electrodes to be formed; circulating an electrochemical bath in a shear zone which is defined by the surface of the layer to be etched and by the surface of a counter electrode; and passing an electric current between the counter electrode and the zones which are not protected by the protective film, said current being conveyed over a line of contacts which is disposed on the surface of the conductive layer perpendicularly to the direction of passage D. In this way, etching homogeneity and network formation precision are improved.

The invention relates to a method and to a device for etching a thin conductive layer based on tin oxide, chromium oxide, indium oxide or a mixture of at least two of these oxides, this being deposited on an insulating plate so as to form an array of conductive electrodes on this substrate.

To produce an array of electrodes on an insulating plate, for example a glass plate, it is sometimes more advantageous and/or more economical to apply the uniform conductive layer to this plate and then etch electrodes in this layer than to apply electrodes directly to the plate.

This is the case, for example, in the production of transparent conductive electrodes on a glass plate or panel intended to form the faceplate of a plasma display: the starting point is then a glass plate covered with a transparent conductive layer based on tin oxide obtained by pyrolytic means; tin oxide layers may thus be produced directly, in line, on glass as it leaves a glass plate manufacturing plant; tin oxide, generally doped with fluorine, is deposited when the glass is still at a temperature of around 600° C., by pyrolytic decomposition of a tin compound; the tin oxide layer obtained has at least three major advantages:
the resistivity of the conductive layer is low enough to be able to form an array of electrodes on the faceplate of a plasma panel; it is generally between 10 and 25 ΩQ/ ;
the conductive layer obtained is chemically extremely stable; thus, this layer suffers no deterioration when a dielectric enamel layer, needed for the operation of the plasma panel, is deposited on this layer and baked; and
compared to vacuum sputtering deposition used elsewhere for forming arrays of transparent electrodes, this deposition method is very inexpensive.

However, this method of producing transparent electrodes has a major drawback because the electro-chemical etching of this layer is particularly difficult to control in an industrial line when very precise geometries are to be obtained.

More specifically, the above method, which is used to etch electrodes, conventionally comprises the following steps:
a protective film having the same patterns as that of said array of electrodes is applied to the conductive layer;
the plate provided with the protective film is run through an electrochemical etching bath;
during the run through, with a counterelectrode immersed in the etching bath, an electric current is made to flow through said bath between said counterelectrode and the immersed areas of the conductive layer of said plate that are unprotected by the film; and
the protective film is removed.

Such a method and a device for implementing it are, for example, described in the following documents:
the article entitled “Electrochemical patterning of tin oxide films” by B. J. Baliga in Journal of the Electrochemical Society 1977, Vol. 124, No. 7, pp. 1059-1060;
the article entitled “Micromachining of tin oxide by electrochemical reduction process” by Y. Matsuo et al., in Journal of the Electrochemical Society, 1998, Vol. 145, No. 9, pp. 3067-3069; and
the following patent applications: U.S. Pat. No. 3,205,155, U.S. Pat. No. 3,507,759, U.S. Pat. No. 3,668,089, U.S. Pat. No. 4,165,989, U.S. Pat. No. 5,227,036 and JP 06-293278.

The nature and the temperature of the bath, the run speed and the current flow conditions are described in these documents.

The drawback of the devices for carrying out the electrochemical etching process, such as those described in the abovementioned documents, is that they do not allow sufficiently uniform etching of the areas of the conductive layer to be etched and do not allow narrow electrodes with a sufficiently precise outline to be formed; the problem is particularly crucial in the case of conductive layers based on tin oxide that are obtained by pyrolysis.

This is because the electrochemical electro-erosion current must be fed into the immersed areas with the thin conductive layer via a current feed electrode in contact with this layer; between the various areas of electrical contact of the thin layer with this electrode and the various areas of this layer being etched in the bath, the current paths have different lengths; since the resistivity of this layer is not insignificant, the shortest current paths become preferential paths, thereby resulting in preferential etching areas; this effect is exacerbated by the thinning of the areas in this layer over the course of etching.

The object of the invention is to avoid the aforementioned drawbacks.

For this purpose, the subject of the invention is a method for etching a thin conductive layer deposited on an insulating plate, so as to form on this plate an array of conductive electrodes in this layer, comprising the steps in which:
before etching, a protective film, having patterns corresponding to the electrodes of said array of electrodes, is applied to said conductive layer;
for the etching, the unprotected areas of the surface of said conductive layer are brought into contact with an electrochemical etching bath and, with a counterelectrode immersed in this bath, an electric current is made to flow through said bath between said counterelectrode and said unprotected areas so as to etch these areas over the entire thickness of said layer;
   characterized in that, during the etching:
said plate is made to run in a direction corresponding to the general direction of the electrodes to be formed;
to make the electric current flow through the bath, the electric current is fed into said unprotected areas along a contact line that are located on the surface of the conductive layer and cutting the run direction; and
said bath is made to circulate through a bath shear zone bounded by the surface of the layer to be etched and by the active surface of said counterelectrode.

In general, after etching, said protective film is removed.

Most of the electrodes of the array, whether they are in the form of straight lines or form circuitous paths, and whether or not they are provided with branches, have a common general direction; according to the invention, it is approximately along this direction that the plate is made to run; thanks to this arrangement, the electric current may be fed from the contact line right into the unprotected areas immersed in the bath without any electrical discontinuity, especially across the electrodes being formed.

The term “active surface of the counterelectrode” is understood to mean the main surface of this counterelectrode which is immersed in the bath, through which main surface most of the electric current passes.

By circulating the bath through the areas of high current density, that is to say in the shear zone, the efficiency and uniformity of the etching are substantially improved.

This way in which the plate runs, this way in which the current is fed and in which the bath is circulated therefore contribute to the uniformity and to the precision of the etching; it is thus easy to obtain an array of electrodes having outlines that are very accurately defined and it is easily possible to produce electrodes of narrow width and/or of complex shapes.

Preferably, the distance between the contact line and that section of the bath shear zone closest to this line is constant over the entire width of the area to be etched.

Thus, the electric current is uniformly distributed over each unprotected area (4) in contact with the bath and during etching; the uniformity of the etching and the precision in the outline of the electrodes of the array are also improved.

According to the most common and simplest arrangement for implementing the method according to the invention:
said contact line is straight and perpendicular to the run direction;
the direction of circulation of the bath through the shear zone coincides with said run direction, in the same sense or in the opposite sense; and
the shear zone has an approximately constant thickness over the entire width of the area to be etched.

The expression “thickness of the shear zone” is understood to mean the distance between the surface of the layer to be etched and the active surface of the counterelectrode.

Preferably, the distance between said contact line and that section of the bath shear zone closest to this line is less than 5 cm.

The lines of current flowing through the conductive layer toward the bath are then considerably shortened, thereby reducing ohmic losses in the conductive layer.

Preferably, the bath shear zone also has an approximately constant thickness along the run direction, over a distance corresponding approximately to the width of the active surface of said counterelectrode.

The width of the shear zone therefore corresponds to that of the counterelectrode; together with the run speed, it determines the maximum time required to etch each surface element to be etched; the width of the counterelectrodes may therefore advantageously be adapted to the desired run speed and to the desired etching time.

Preferably, the thickness of said shear zone is between 0.1 mm and 5 mm.

There is a better compromise between a high shear rate of the bath, favorable to etchping efficiency, and the risks of a short circuit as it runs between the surface to be etched and the counterelectrode.

Preferably, the flow of the bath circulating through said shear zone is distributed approximately uniformly over the entire width of the area to be etched.

The uniformity of the etching is thus improved.

The invention may also have one or more of the following features:
the thin conductive layer is based on tin oxide, chromium oxide, indium oxide or a mixture of at least two of these oxides;
the thin conductive layer is deposited on the insulating plate by pyrolytic means;
the electrochemical etching bath comprises at least one acid chosen from the group consisting of hydrochloric acid, sulfuric acid, nitric acid, chromic acid, acetic acid and formic acid;
the counterelectrode serves as anode;
the mean electric current density in the conductive layer in contact with the bath is greater than 1 A/dm², preferably greater than 10 A/dm²;
the temperature of said bath is greater than or equal to 30° C.; and
the insulating plate is made of glass.

The subject of the invention is also a device for etching areas of a thin conductive layer placed on an insulating plate, which can be used for implementing the etching step of the method as claimed in any one of the preceding claims, comprising:
means for making this plate run along a plane run path so that the surface to be etched is brought into contact with the etching bath;
means for feeding an electric current into said conductive layer before contact with the bath;
a counterelectrode, immersed in said bath, for return of the electric current;
means for making an electric current flow through said bath between said current feed means and the current return counterelectrode;
   characterized
in that the electric current feed means comprise a rail suitable for coming into contact with the surface of said conductive layer of the plate along the run path, this rail being placed in such a way that the contact line of this rail on this layer cuts this run path; and
in that it furthermore includes means for making the bath circulate between the active surface of the counterelectrode and the run path, this bath circulation zone forming a shear zone having an upstream opening and a downstream opening of the run path.

Preferably, the rail is adapted so that the distance between said contact line and that section of the shear zone closest to this line is constant over the entire width of the area to be etched; depending on the sense of the bath circulation, this closest zone corresponds either to the upstream opening or to the downstream opening of the run path.

According to the most common and simplest arrangement, in the device according to the invention:
said rail is straight and perpendicular to the run direction;
the distance between the active surface of the counterelectrode and the run path is approximately constant over the entire width of the area to be etched; and
the means for making the bath circulate are designed to make the bath circulate through the shear zone along the same direction as that in which the plate runs, in the same sense or the opposite sense.

Preferably, the distance between said contact line and that section of the shear zone closest to this line is less than 5 cm.

Preferably, the active surface of the counterelectrode has a plane main part lying parallel to the run path.

Preferably, the distance between the active surface of the counterelectrode and the run path is between 0.1 mm and 5 mm.

Preferably, the means for making the bath circulate include bath-stream-distributing means suitable for obtaining a constant bath flow rate over the entire width of the openings of the shear zone.

Preferably, the bath circulation means comprise an ejection nozzle that extends at least over the entire width of the layer to be etched and its opening is directed toward one of the openings of the shear zone.

Preferably, the circulation means are suitable for forcing the bath ejected by the nozzle to circulate through said shear zone.

Preferably, the device according to the invention comprises means for recovering the bath exiting one of the openings of the shear zone and means for recirculating the recovered bath.

Preferably, the device according to the invention comprises means for wiping the etched surface on exiting the bath.

The object of the invention is also the use of the method and/or of the device according to the invention for manufacturing the front panel or faceplate of a display, which panel is provided with at least one array of electrodes; preferably, the manufacture of said panel then comprises the application of a dielectric enamel layer to said array and the baking of this enamel layer.

The invention will be more clearly understood from reading the description that follows, given by way of non-limiting example and with reference to the appended figures in which:

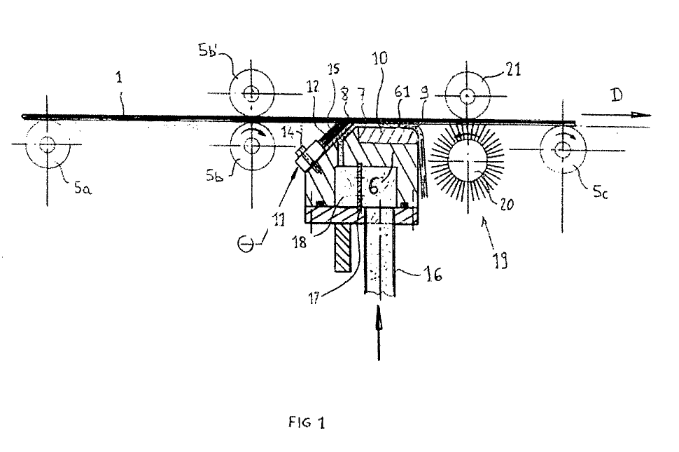

FIG. 1 shows a cross-sectional view of a preferred embodiment of the device according to the invention; and

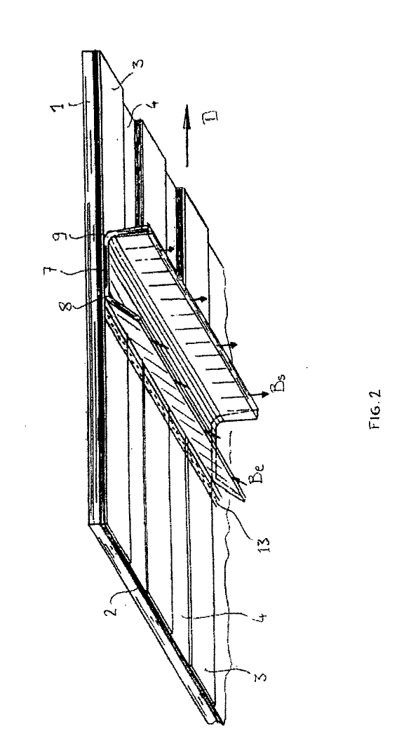

FIG. 2 shows a perspective view of a running plate and of a circulating bath in the device according to FIG. 1.

Referring to FIG. 2, an insulating glass plate 1 comprises, on its lower face, a conductive layer 2 based on tin oxide, deposited in this case by pyrolytic means, in which layer it is desired to etch an array of electrodes; the thickness of this layer is around 400 nm and its resistivity is around 15 Ω/(ohms/square).

The conductive layer 2 is coated in a manner known per se with a protective film 3 having patterns that correspond to the electrodes of the array to be etched; between the patterns in this film 3, the surfaces unprotected by the film form areas 4 of the conductive layer to be etched; the areas to be etched are distributed over the entire width of the plate, which thus forms the overall width of the area to be etched.

The protective film (with its patterns) is applied in a manner known per se. In particular, it may be applied by photolithography or by screen printing; its thickness is generally between 5 and 30 μm; the composition and the adhesion of this film are adapted so as to withstand the electrochemical etching operations that will be described below.

As shown in FIG. 1, and also in FIG. 2, the etching device according to the invention has, according to a preferred embodiment, the following components:
means for making the plate 1 run in the direction and the sense that are indicated by the arrow D, along a plane run path; these means comprise here running rolls 5a, 5b, 5b′, 5c that are actuated in a manner known per se in the direction of rotation indicated by the arrows and define the run path of the plate; hereafter, the plane of the run path corresponds more precisely to that of the conductive layer, that is to say to the lower surface of the plate;
a fixed transverse member 6 extending at least over the entire width of the layer to be etched, that surface 61 of the transverse member that is closest to the run path defines, with this path, a shear zone 7 having an approximately constant thickness Ec; here, the transverse member 6 is straight and lies perpendicular to the run direction; here, the surface 61 is plane and parallel to the run path in such a way that the shear zone 7 also has a constant thickness Ec along the run path; the shear zone 7 therefore forms a rectangular parallelepiped forming a duct for circulation of the etching bath, said duct having an upstream opening 8 and the downstream opening 9;
means for making an etching bath circulate through this shear zone 7 in the run direction, here in the same sense as the run direction, in such a way that the etching bath penetrates this zone via the upstream opening 8 that serves as inlet and exits said zone via the downstream opening 9 that serves as outlet; these means comprise an ejection nozzle that extends over at least the entire width of the layer to be etched and the opening of which is directed toward one of the openings of the shear zone, in this case the upstream opening 8; preferably, as shown in FIGS. 1 and 2, the opening of the ejection nozzle coincides with the opening 8 of the shear zone 7, so as to force the bath ejected by this nozzle to circulate through the shear zone 7; other embodiments, without forced circulation, are conceivable without departing from the invention;
means for feeding an electric current into the conductive layer 4 before it comes into contact with the bath in the shear zone 7, these means consequently being positioned on the run path upstream of this shear zone 7; these means comprise a fixed rail 11 comprising contactors 12 that are intended to come into direct contact with the unprotected areas 4 of the conductive layer 2 of the plate 1 on the run path, said rail being placed in such a way that the contact line 13 of these contactors cuts this run path and lies over the entire width of the layer to be etched; these contactors 12 here are also in contact with the protective film 3, in the covered areas and the protected areas of the conductive layer 2; since the rail 11 here is straight and lies perpendicular to the run direction, the contact line 13 is also straight and perpendicular to the run direction; here, the rail 11 is fastened to the transverse member 6 by fastening means 14;
a counterelectrode 10 for return of the electric current, fastened to the transverse member 6, the active surface of which counterelectrode forms at least one part of the surface 61 closest to the run path of the transverse member 6; this counterelectrode 10 being made of conductive material;
means (not shown) for making an electric current flow through the bath that circulates through the shear zone 7 between the current feed rail 11 and the counterelectrode 10.

In this stripping device, the section of the bath shear zone nearest to the contact line 13 corresponds, in this case, to the upstream opening 8 of the shear zone 7.

Since the transverse member 6 here supports both the current feed contact rail 11 and the current return counterelectrode 10, this transverse member 6 here is made of insulating material.

According to the embodiment in FIG. 1, the transverse member 6 also serves as nozzle for ejecting the bath into the shear zone 7; for this purpose, it includes an internal cavity 18 for distributing the stream emerging in at least one duct bounded by a plate 15 secured to the transverse member 6, which duct in turn emerges via the ejection nozzle in the upstream opening 8 of the shear zone 7; this cavity 18 is supplied by a bath feed pipe 16 in turn connected to bath recirculation means (not shown); the cavity 18 makes it possible to obtain a constant bath flow rate over the entire width of the opening 8; a mesh 17 (or several such meshes) is placed across this cavity 18 in order to further improve the uniform distribution of the flow over the entire length of the bath ejection nozzle; in the entire section of the shear zone of the bath perpendicular to the run direction, the bath flow rate per unit length of this section is thus approximately constant over the entire width of the area to be etched; other bath-distributing means may be used without departing from the invention.

The counterelectrode 10 extends over the entire width of the device and, in the run direction, over an active width that may be adjustable; in order to adjust it, various sets of counterelectrodes having different widths may be used; the counterelectrode 10 is made of titanium for example; the active surface 61 may be formed from a thin layer of platinum, for example with a thickness of around 5 μm; the use of platinum prevents passivation.

Preferably, the thickness Ec of the shear zone 7 is between 0.1 and 5 mm, for example equal to 3 or 4 mm.

Advantageously as shown in FIG. 1, the distance that separates the contact line 13 of the upstream opening 8 from the bath shear zone 7 (see FIG. 2) is between 1 and 5 mm; referring to FIG. 1, this distance here depends on the thickness of the plate 15 that defines the bath ejection nozzle duct; this plate 15 is made of insulating material in order to prevent the current from passing directly between the contactors 12 and the bath.

Without departing from the invention, the contactors 12 may be positioned a certain distance from the plate 15; the plate 15 then serves as a “nonreturn blade”.

The contactors 12 supported by the rail 11 may, for example, be formed from graphite fibers or carbon fibers; the diameter of these fibers is preferably substantially smaller than the width of the areas to be etched.

The etching device also includes means (not shown) for recovering the bath exiting the shear zone via the downstream opening 9, hence enabling the bath to be reinjected into the recirculation means.

Finally, at the exit of the shear zone 7, the etching device includes wiping means 19 that are suitable for removing the bath entrained by the running plate, or indeed also to remove any solid residue from the conductive layer to be etched; these means comprise here a brush roll 20 and a backing roll 21.

According to a variant of the invention, the device includes, also at the exit of the shear zone 7, means for removing the protective film 3 from the surface of the running plate, for example by spraying an alkaline bath onto this film.

The etching or etching step of the method according to the invention will now be described.

An etching bath is prepared by adapting its composition to the nature of the conductive layer to be etched, in accordance with the teachings of the documents mentioned above in the introduction; in the case of a layer based on pyrolytic tin oxide with a thickness of 0.4 μm, a 5 wt % hydrochloric acid bath at room temperature is used for example.

The run speed of the plate 1 is defined in such a way that the resident time of this plate in the shear zone 7 is long enough to etch the unprotected areas of the conductive layer over its entire thickness; it may therefore be seen that the maximum run speed permitted depends on the etching conditions and the nature and thickness of the conductive layer to be etched; in practice, the run speed may be between 0.1 and 2 m/min, for example around 0.2 to 0.3 m/min.

While the plate 1 with its downwardly directed conductive layer 2 is running, the etching bath is injected using bath recirculation means into the shear zone 7 across the transverse member 6 and the ejection nozzle; the arrows Be and Bs in FIG. 2 indicate the circulation of the bath through the shear zone 7.

While the plate 1 is running and the etching bath is circulating through the shear zone 7, an electric current is made to flow between the rail 11 and the counterelectrode 10; the succession of electric contacts between the contactors 12 carried by the rail and the unprotected areas 4 to be etched, which are arranged between the patterns of the insulating film 3 and distributed along the rail, forms the contact line 13 which cuts the run path of the plate 1; starting from these contacts, the electric current is conducted into the thickness of the conductive layer as far as portions of areas 4 to be etched that are in contact with the bath; the electric current then passes through the bath over the thickness Ec of the shear zone, between the surface of the areas 4 to be etched that are in contact with the bath and the active surface 61 of the counterelectrode; the current lines are therefore particularly short, this having the advantage of limiting ohmic losses; the electric current fed to the rail 11 may exceed 5 A/dm, generally at a maximum voltage of 20 V between the rail 11 and the counterelectrode 10; thus, for a counterelectrode width of 2 cm, the current density may exceed 25 A/dm²; to achieve effective etching, the current density is preferably greater than 1 A/dm², or even greater than 10 A/dm².

Preferably, the rail 11 serves as cathode and the counterelectrode 10 serves as anode, as shown in FIG. 1.

Good etching results have been obtained on a layer of pyrolytic tin oxide 0.4 μm in thickness using a 5 wt % HCl solution at room temperature under the following conditions: shear zone thickness Ec=3 mm; width of the plate to be etched=600 mm; bath flow rate around 10 l/min in this zone; counterelectrode width=2 cm, the counterelectrode serving as anode; run speed=0.3 m/min; the electric current=35 A; distance between the contact line 13 and the upstream opening 8 of the shear zone=5 mm.

It should be noted that the reduced distance between the contact line 13 and the upstream opening 8 of the shear zone is an important factor in limiting ohmic losses; this distance is preferably less than 5 cm, or even, if possible, as in this case, less than 1 cm.

At the run exit, the wiping means remove the bath entrained on the lower surface of the plate.

What is then obtained is a plate provided with an array of conductive electrodes covered with a protective film; this protective film is then removed from the etched plate in a manner known per se.

According to a variant of the invention, when the electrodes to be etched are intended to be coated with an insulating layer, especially in the case of plasma panels, the protective film may, on the contrary stay in place; the protective film used is then matched to the insulating layer that it is desired to form on the electrodes; in the case of plasma displays, this film then generally comprises a dielectric mineral composition; after the panel provided with its array of electrodes has been baked, the electrodes are then coated with a dielectric layer.

The method that has just been described makes it possible to achieve uniform etching of the conductive layer over the entire width of the plate and thus obtain electrodes that are narrow and/or of complex shape with a high etch rate; it has thus been possible to etch arrays of electrodes at rates of more than 50 cm/min; this method is particularly beneficial when the conductive layer to be etched is based on pyrolytic tin oxide; thanks to the invention, an array of electrodes can be etched really easily and precisely in this type of layer.

Without departing from the invention, it is possible to use a device in which, unlike that described above, the plate 1 to be etched is fixed and it is the transverse member 6 that moves.

The method according to the invention is also applicable to other insulating plates provided with a conductive layer, provided that the conductive layer can be etched and etched by an electrochemical method; instead of being made of glass, the plate may, for example, be made of ceramic or glass-ceramic; this plate may be provided with another conductive layer on the other face; instead of being made of pyrolytic tin oxide, the conductive layer to be etched may in particular be based on nonpyrolytic tin oxide, on indium oxide or on a mixture of these two oxides (ITO).

The plate provided with its array of electrodes obtained by the method according to the invention can advantageously be used in any type of display panel having a panel provided with at least one array of electrodes, especially plasma displays, liquid-crystal displays and light-emitting diode displays, such as OLED displays; when the electrodes thus etched are transparent, this plate then advantageously serves for the manufacture of the front panel of the display.

To manufacture the front panel of a plasma display, a layer of dielectric enamel is applied to the array of electrodes on this plate and is then baked; when the initial conductive layer is based on pyrolytic tin oxide, no impairment of the array of electrodes upon baking the dielectric enamel is observed.

1. A method for etching a thin conductive layer deposited on an insulating plate, so as to form on this plate an array of conductive electrodes in this layer, comprising the steps in which:
before etching, a protective film, having patterns corresponding to the electrodes of said array of electrodes, is applied to said conductive layer;
for the etching, the unprotected areas of the surface of said conductive layer are brought into contact with an electrochemical etching bath and, with a counterelectrode immersed in this bath, an electric current is made to flow through said bath between said counterelectrode and said unprotected areas so as to etch these areas over the entire thickness of said layer; wherein, during the etching:
said plate is made to run in a direction corresponding to the general direction of the electrodes to be formed;
to make the electric current flow through the bath, the electric current is fed into said unprotected areas along a contact line that are located on the surface of the conductive layer and cutting the run direction; and
said bath is made to circulate through a bath shear zone bounded by the surface of the layer to be etched and by the active surface of said counterelectrode.

2. The method as claimed in claim 1, wherein the distance between said contact line and that section of the bath shear zone closest to this line is constant over the entire width of the area to be etched.

3. The method as claimed in claim 2, wherein:
said contact line is straight and perpendicular to the run direction;
the direction of circulation of the bath through the shear zone coincides with said run direction, in the same sense or in the opposite sense; and
the shear zone has an approximately constant thickness over the entire width of the area to be etched.

4. The method as claimed in claim 3, wherein the distance between said contact line and that section of the bath shear zone closest to this line is less than 5 cm.

5. The method as claimed in claim 3, wherein the bath shear zone also has an approximately constant thickness along the run direction, over a distance corresponding approximately to the width of the active surface of said counterelectrode.

6. The method as claimed in claim 5, wherein the thickness of said shear zone is between 0.1 mm and 5 mm.

7. The method as claimed in claim 3, wherein the flow of the bath circulating through said shear zone is distributed approximately uniformly over the entire width of the area to be etched.

8. The method as claimed in claim 1, wherein said thin conductive layer is based on tin oxide, chromium oxide, indium oxide or a mixture of at least two of these oxides.

9. The method as claimed in claim 8, wherein said thin conductive layer is deposited on the insulating plate by pyrolytic means.

10. The method as claimed in claim 8, wherein the electrochemical etching bath comprises at least one acid chosen from the group consisting of hydrochloric acid, sulfuric acid, nitric acid, chromic acid, acetic acid and formic acid.

11. The method as claimed in claim 8, wherein said counterelectrode serves as anode.

12. The method as claimed in claim 8, wherein the mean electric current density in the conductive layer in contact with the bath is greater than 1 A/dm².

13. The method as claimed in claim 1, wherein the temperature of said bath is greater than or equal to 30° C.

14. The method as claimed in claim 1, wherein said insulating plate is made of glass.

15. A device for etching areas of a thin conductive layer placed on an insulating plate, which can be used for implementing the etching step of the method as claimed in claim 1, comprising:
means for making this plate run along a plane run path so that the surface to be etched is brought into contact with the etching bath;
means for feeding an electric current into said conductive layer before contact with the bath;
a counterelectrode immersed in said bath, for return of the electric current;
means for making an electric current flow through said bath between said current feed means and the current return counterelectrode; wherein:
in that the electric current feed means comprise a rail suitable for coming into contact with the surface of said conductive layer of the plate along the run path, this rail being placed in such a way that the contact line of this rail on this layer cuts this run path; and
in that it furthermore includes means for making the bath circulate between the active surface of the counterelectrode and the run path, this bath circulation zone forming a shear zone Shaving an upstream opening and a downstream opening of the run path.

16. The device as claimed in claim 15, wherein said rail is adapted so that the distance between said contact line and that section of the shear zone closest to this line is constant over the entire width of the area to be etched.

17. The device as claimed in claim 16, wherein:
said rail is straight and perpendicular to the run direction;
the distance between the active surface of the counterelectrode and the run path is approximately constant over the entire width of the area to be etched; and
the means for making the bath circulate are designed to make the bath circulate through the shear zone along the same direction as that in which the plate runs, in the same sense or the opposite sense.

18. The device as claimed in claim 17, wherein the distance between said contact line and that section of the shear zone closest to this line is less than 5 cm.

19. The device as claimed in claim 17, wherein the active surface of the counterelectrode has a plane main part lying parallel to the run path.

20. The device as claimed in claim 19, wherein the distance between the active surface of the counterelectrode and the run path is between 0.1 mm and 5 mm.

21. The device as claimed in claim 17, wherein the means for making the bath circulate include bath-stream-distributing means suitable for obtaining a constant bath flow rate over the entire width of the openings of the shear zone.

22. The device as claimed in claim 21, characterized in that wherein the bath circulation means comprise an ejection nozzle that extends at least over the entire width of the layer to be etched and its opening is directed toward one of the openings of the shear zone.

23. The device as claimed in claim 22, characterized in that wherein the circulation means are suitable for forcing the bath ejected by the nozzle to circulate through said shear zone.

24. The device as claimed in claim 15, wherein it comprises means for recovering the bath exiting one of the openings of the shear zone and means for recirculating the recovered bath.

25. The device as claimed in claim 15, wherein it comprises means for wiping the etched surface on exiting the bath.

26. The use of the method or device as claimed in any one of claim 1 in the manufacture of the front panel or faceplate of a display, which panel is provided with at least one array of electrodes.

27. The use as claimed in claim 26, wherein the manufacture of said panel includes the application of a dielectric enamel layer to said array and the baking of this enamel layer.
